(19) United States
(12) Patent Application Publication
(10) Pub. No.: US 2023/0121432 A1
(43) Pub. Date: Apr. 20, 2023

(54) OPTICAL SENSING CIRCUIT AND OPTICAL SENSING METHOD

(71) Applicant: Egis Technology Inc., Hsinchu City (TW)

(72) Inventors: Jing-Min Chen, Hsinchu City (TW); Yao-Sheng Hu, Hsinchu City (TW)

(73) Assignee: Egis Technology Inc., Hsinchu City (TW)

(21) Appl. No.: 17/847,206

(22) Filed: Jun. 23, 2022

Related U.S. Application Data
(60) Provisional application No. 63/255,966, filed on Oct. 15, 2021.

(30) Foreign Application Priority Data
Apr. 29, 2022 (TW) 111116354

(51) Int. Cl. G01J 1/42; G01J 1/02; G01J 1/44

(52) U.S. Cl. CPC G01J 1/4228; G01J 1/0228; G01J 1/44; G01J 2001/444; G01J 2001/446

(57) ABSTRACT

An optical sensing circuit and an optical sensing method are provided. The optical sensing circuit includes a first photosensitive unit, a second photosensitive unit, an arithmetic unit, and a control unit. The first photosensitive unit and the second photosensitive unit provide a sensing current during a light sensing period. The arithmetic unit generates a combined current according to the sensing current during the light sensing period. The control unit generates a first sensed value and a second sensed value according to the combined current.

### CROSS-REFERENCE TO RELATED APPLICATION

This application claims the priority benefit of U.S. Provisional Application No. 63/255,966, filed on Oct. 15, 2021 and Taiwan Application No. 111116354, filed on Apr. 29, 2022. The entirety of each of the above-mentioned patent applications is hereby incorporated by reference herein and made a part of this specification.

### BACKGROUND

### Technical Field

The disclosure relates to a sensing technology, and more particularly to an optical sensing circuit and an optical sensing method.

### Description of Related Art

Each sensing pixel in a conventional optical sensor corresponds to a readout circuit equipped with an independent analog to digital converter (ADC) to read out a sensed result of a photodiode (PD) in the sensing pixel. In other words, the excessive number of the ADCs in the conventional optical sensor leads to the overly large circuit area occupied by the readout circuit, which even results in the difficulty in effectively reducing the volume of the optical sensor.

### SUMMARY

The disclosure provides an optical sensing circuit and an optical sensing method capable of effectively generating sensed values and reducing a circuit area occupied by a readout circuit of the optical sensing circuit.

In an embodiment of the disclosure, an optical sensing circuit includes a first photosensitive unit, a second photosensitive unit, an arithmetic unit, and a control unit. The first photosensitive unit and the second photosensitive unit are configured to provide a sensing current during a light sensing period. The arithmetic unit is configured to generate a combined current according to the sensing current during the light sensing period. The control unit is coupled to the arithmetic unit to generate a first sensed value of the first photosensitive unit and a second sensed value of the second photosensitive unit according to the combined current.

In an embodiment of the disclosure, an optical sensing method includes following steps: a sensing current is provided during a light sensing period by a first photosensitive unit and a second photosensitive unit, a combined current is generated according to the sensing current during the light sensing period by an arithmetic unit, and a first sensed value of the first photosensitive unit and a second sensed value of the second photosensitive unit are generated according to the combined current by a control unit.

In view of the above, in the optical sensing circuit and the optical sensing method provided in one or more embodiments of the disclosure, the first photosensitive unit and the second photosensitive unit may share one arithmetic unit and one control circuit to generate the first sensed value and the second sensed value, so as to effectively reduce the circuit area occupied by the optical sensing circuit.

In order for the features and advantages of the disclosure to be more comprehensible, the following specific embodiments are described in detail in conjunction with the drawings.

### BRIEF DESCRIPTION OF THE DRAWINGS

FIG. 1 is a schematic view of an optical sensing circuit according to an embodiment of the disclosure.

FIG. 2 is a flowchart of an optical sensing method according to an embodiment of the disclosure.

FIG. 3 is a schematic view of a timing sequence of signals according to an embodiment of the disclosure.

FIG. 4 is a schematic view of an arithmetic unit according to another embodiment of the disclosure.

FIG. 5 is a schematic view of a timing sequence of signals according to another embodiment of the disclosure.

### DETAILED DESCRIPTION OF DISCLOSED EMBODIMENTS

Embodiments of the disclosure are described in detail with reference to the drawings for betting understanding of the disclosure. Whenever possible, devices/components/steps represented by the same reference numbers in the drawings and embodiments represent the same or similar parts.

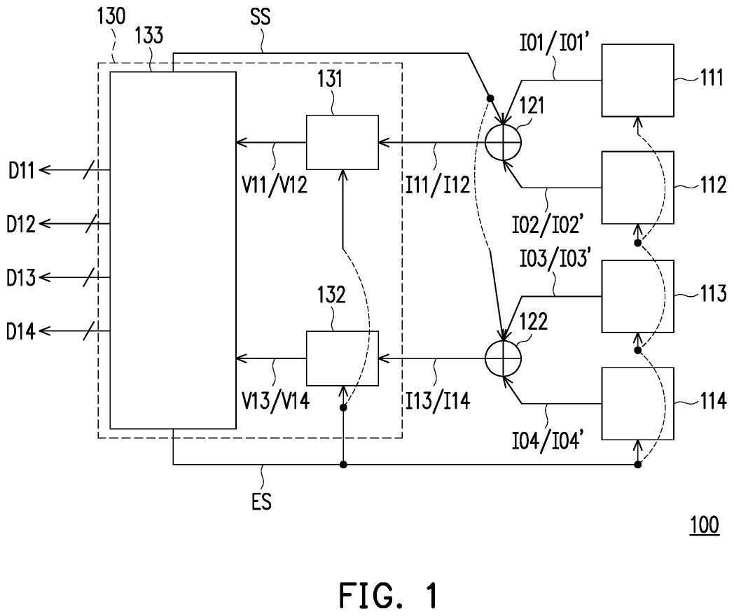

FIG. 1 is a schematic view of an optical sensing circuit according to an embodiment of the disclosure. With reference to FIG. 1, an optical sensing circuit 100 includes a first photosensitive unit 111, a second photosensitive unit 112, a third photosensitive unit 113, a fourth photosensitive unit 114, a first arithmetic unit 121, a second arithmetic unit 122, and a control unit 130. The control unit 130 includes a first analog to digital converter (ADC) 131, a second ADC 132, and a control circuit 133. The first ADC 131, the second ADC 132, and the control circuit 133 may be considered as a part of a readout circuit of the optical sensing circuit 100.

In this embodiment, the first photosensitive unit 111 and the second photosensitive unit 112 are coupled to a first input terminal and a second input terminal of the first arithmetic unit 121, respectively. An output terminal of the first arithmetic unit 121 is coupled to an input terminal of the first ADC 131. The third photosensitive unit 113 and the fourth photosensitive unit 114 are coupled to a first input terminal and a second input terminal of the second arithmetic unit 122, respectively. An output terminal of the second arithmetic unit 122 is coupled to an input terminal of the second ADC 132. An output terminal of the first ADC 131 is coupled to the control circuit 133, and an output terminal of the second ADC 132 is coupled to the control circuit 133.

In this embodiment, the control circuit 133 may be, for instance, a digital signal processor (DSP), a programmable logic controller (PLC), or an application specific integrated circuit (ASIC), which should however not be construed as a limitation in the disclosure.

In this embodiment, the first arithmetic unit 121 and the second arithmetic unit 122 are further coupled to a switch signal output terminal of the control circuit 133 to obtain a switch signal SS provided by the control circuit 133. The first photosensitive unit 111, the second photosensitive unit 112, the third photosensitive unit 113, the fourth photosensitive unit 114, the first ADC 131, and the second ADC 132 are further coupled to an enabling signal output terminal of the control circuit 133 to obtain an enabling signal ES provided by the control circuit 133.

In this embodiment, the optical sensing circuit 100 may be applied to sense ambient light or flashing light sensing, which should however not be construed as a limitation in the disclosure. The first photosensitive unit 111, the second photosensitive unit 112, the third photosensitive unit 113, and the fourth photosensitive unit 114 may be a photodiode (PD) respectively and may respectively act as a sensing pixel of different colors. The first photosensitive unit 111, the second photosensitive unit 112, the third photosensitive unit 113, and the fourth photosensitive unit 114 may sense the ambient light or the flashing light to generate sensed values corresponding to different colors, respectively. For instance, the respective PD of the first photosensitive unit 111, the second photosensitive unit 112, and the third photosensitive unit 113 may be equipped with a color filter and may be configured to sense red light waveband, green light waveband, and blue light waveband in a visible light signal, respectively. The fourth photosensitive unit 114 may be configured to sense all wavebands of the visible light signal, so that the control unit 130 may generate sensed values of the red light, the green light, the blue light, and the visible light.

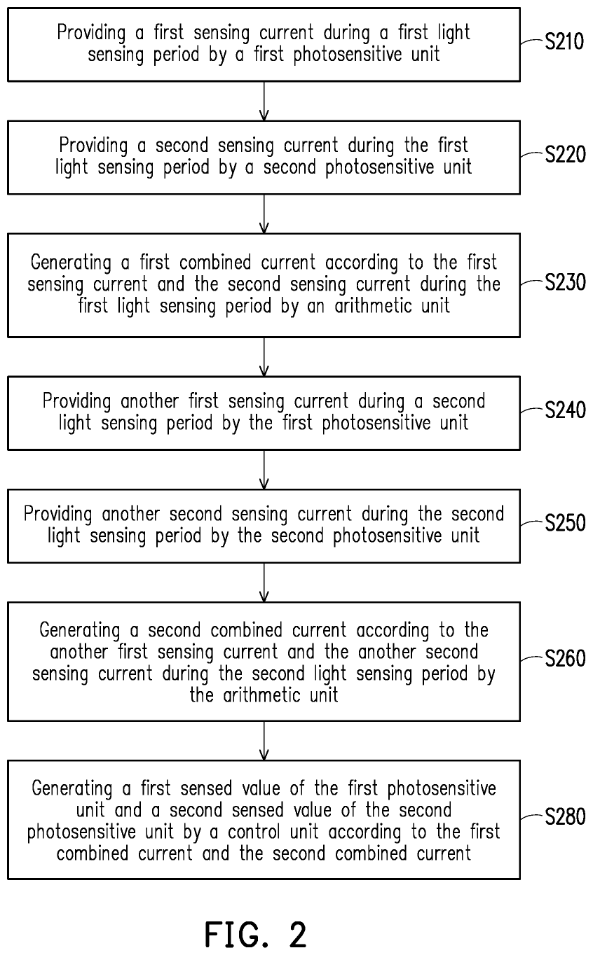

In this embodiment, taking the first photosensitive unit 111 and the second photosensitive unit 112 as examples, the first photosensitive unit 111 and the second photosensitive unit 112 may provide sensing currents (I01/I01′/I02/I02′) during a light sensing period. The first arithmetic unit 121 may generate a combined current (I11/I12) according to the sensing current during the light sensing period. The control unit 130 may generate a first sensed value of the first photosensitive unit 111 and a second sensed value of the second photosensitive unit 112 according to the combined current (I11/I12). Specific implementation manner of each step provided above will be elaborated below with reference to FIG. 2.

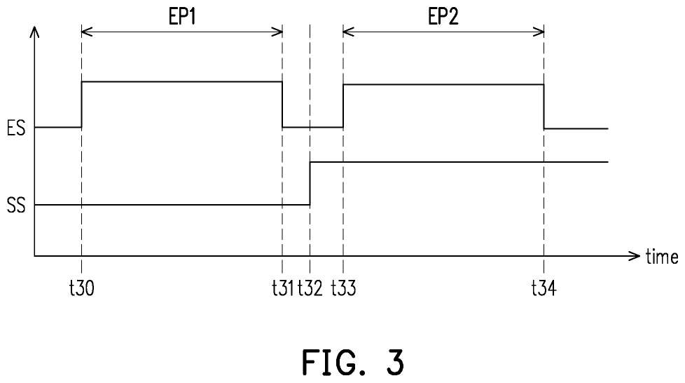

FIG. 2 is a flowchart of an optical sensing method according to an embodiment of the disclosure. FIG. 3 is a schematic view of a timing sequence of signals according to an embodiment of the disclosure. With reference to FIG. 1 to FIG. 3, the optical sensing circuit 100 may perform following steps to obtain the sensed values. In step S210, the optical sensing circuit 100 may provide a first sensing current I01 during a first light sensing period EP1 by the first photosensitive unit 111. In step S220, the optical sensing circuit 100 may provide a second sensing current I02 during the first light sensing period EP1 by the second photosensitive unit 112. The first photosensitive unit 111 and the second photosensitive unit 112 may receive the enabling signal ES provided by the control circuit 133, respectively, so as to perform an exposure operation during the first light sensing period EP1 (from a timing t30 to a timing t31). As shown in FIG. 3, the enabling signal ES may be, for instance, switched from a low voltage level to a high voltage level at the timing t30, so that the first photosensitive unit 111 and the second photosensitive unit 112 perform the exposure operation from the timing t30 to the timing t31 and output the first sensing current I01 and the second sensing current I02.

In step S230, the optical sensing circuit 100 may generate a first combined current I11 according to the first sensing current I01 and the second sensing current I02 during the first light sensing period EP1 by the first arithmetic unit 121. As shown in FIG. 3, the switch signal SS may, for instance, stay at the low voltage level from the timing t30 to a timing t32, so that the first arithmetic unit 121 is being operated in a first operation mode (e.g., performing an adding step). For instance, the first arithmetic unit 121 may add the first sensing current I01 and the second sensing current I02 generated during the first light sensing period EP1 to generate the first combined current I11 (I11=I01+I02).

In step S240, the optical sensing circuit 100 may provide another first sensing current I01′ during a second light sensing period EP2 by the first photosensitive unit 111. In step S250, the optical sensing circuit 100 may provide another second sensing current I02′ during the second light sensing period EP2 by the second photosensitive unit 112. The first photosensitive unit 111 and the second photosensitive unit 112 may receive the enabling signal ES provided by the control circuit 133, respectively, so as to respectively perform an exposure operation during the second light sensing period EP2. As shown in FIG. 3, the enabling signal ES may be switched from the low voltage level to the high voltage level at a timing t33, for instance, so that the first photosensitive unit 111 and the second photosensitive unit 112 perform another exposure operation from the timing t33 to a timing t34 to output another first sensing current I01′ and another second sensing current I02′.

In step S260, the optical sensing circuit 100 may generate a second combined current I12 according to the another first sensing current I01′ and the another second sensing current I02′ during the second light sensing period EP2 by the first arithmetic unit 121. As shown in FIG. 3, the switch signal SS is switched from the low voltage level to the high voltage level at the timing t32, and the switch signal SS may stay at the high voltage level from the timing t32 to the timing t34, so that the first arithmetic unit 121 is being operated at a second operation mode (e.g., performing a subtracting step). For instance, the first arithmetic unit 121 may subtract the another first sensing current I01′ and the another second sensing current I02′ from each other to generate a second combined current I12 (I12=I01′−I02′).

In step S270, the optical sensing circuit 100 may generate a first sensed value D11 of the first photosensitive unit 111 and a second sensed value D12 of the second photosensitive unit 112 by the control unit 130 according to the first combined current I11 and the second combined current I12. In this embodiment, the first ADC 131 may convert the first combined current I11 and the second combined current I12 into a first digital signal V11 and a second digital signal V12. Next, the control circuit 133 may calculate the first sensed value and the second sensed value according to a first phase count value of the first digital signal V11 and a second phase count value of the second digital signal V12.

For instance, the first phase count value may represent a digital value of the first digital signal V11 and may correspond to a current value of the first combined current I11 (I11=I01+I02), and the second phase count value may represent a digital value of the second digital signal V12 and may correspond to a current value of the second combined current I12 (I12=I01′−I02′). It is assumed that the first sensing current I01 and the another first sensing current I01′ are respectively obtained in two exposure periods that are close to each other and have the same exposure time length, and thus the value of the first sensing current I01 may be close to or equal to the value of the another first sensing current I01′. Thereby, the control circuit 133 may add the first phase count value and the second phase count value to obtain the first arithmetic value, and the first arithmetic value may correspond to a value close or equal to twice the first sensing current I01 (I11+I12=2×I01). Similarly, it is assumed that the second sensing current I02 and the another second sensing current I02′ are respectively obtained in two exposure periods that are close to each other and have the same exposure time length, and thus the value of the second sensing current I02 may be close to or equal to the value of the another second sensing current I02′. Thereby, the control circuit 133 may subtract the first phase count value and the second phase count value from each other to obtain the second arithmetic value, and the second arithmetic value may correspond to a value close or equal to twice the second sensing current I02 (I11−I12=2×I02). As a result, the control circuit 133 may divide the first arithmetic value and the second arithmetic value by a reference value (the reference value may be, for instance, 2) to obtain the first sensed value D11 of the first photosensitive unit 111 and the second sensed value D12 of the second photosensitive unit 112. The first sensed value D11 may be close or equal to the value obtained by directly converting the first sensing current I01 (or the another first sensing current I01′), i.e., equal or analogous to the sensed result of the first photosensitive unit 111 during the first light sensing period EP1 (or the second light sensing period EP2). The second sensed value D12 may be close or equal to the value obtained by directly converting the second sensing current I02 (or the another second sensing current I02′), i.e., equal or analogous to the sensed result of the second photosensitive unit 112 during the first light sensing period EP (or the second light sensing period EP2). In addition, the reference value may be determined according to the sum of the first light sensing period EP1 and the second light sensing period EP2 and a multiple of the actual time length of one frame, and the reference value is a positive integer.

Note that the detailed manner of calculating and generating a third sensed value D13 and a fourth sensed value D14 of the third photosensitive unit 113 and the fourth photosensitive unit 114 may be deduced from the descriptions above and thus is briefly explained below.

In this embodiment, the optical sensing circuit 100 may provide a third sensing current I03 during the first light sensing period EP1 by the third photosensitive unit 113. The optical sensing circuit 100 may provide a fourth sensing current I04 during the first light sensing period EP1 by the fourth photosensitive unit 114. The third photosensitive unit 113 and the fourth photosensitive unit 114 may receive the enabling signal ES provided by the control circuit 133, respectively, so as to respectively perform an exposure operation during the first light sensing period EP1. The optical sensing circuit 100 may generate a third combined current I13 according to the third sensing current I03 and the fourth sensing current I04 during the first light sensing period EP1 by the second arithmetic unit 122. For instance, the second arithmetic unit 122 may add the third sensing current I03 and the fourth sensing current I04 generated during the first light sensing period EP1 to generate the third combined current I13 (I13=I03+I04).

In this embodiment, the optical sensing circuit 100 may provide another third sensing current I03′ in the second light sensing period EP2 through the third sensing current I03. The optical sensing circuit 100 may provide another fourth sensing current I04′ during the second light sensing period EP2 by the fourth photosensitive unit 114. The third photosensitive unit 113 and the fourth photosensitive unit 114 may receive the enabling signal ES provided by the control circuit 133, respectively, so as to respectively perform an exposure operation during the second light sensing period EP2. The optical sensing circuit 100 may generate a fourth combined current I14 according to the another third sensing current I03′ and the another fourth sensing current I04′ during the second light sensing period EP2 by the second arithmetic unit 122. For instance, the second arithmetic unit 122 may subtract the another third sensing current I03′ and the another fourth sensing current I04′ from each other to generate the fourth combined current I14 (I14=I03′−I04′). Thereby, the optical sensing circuit 100 may generate the third sensed value D13 of the third photosensitive unit 113 and the fourth sensed value D14 of the fourth photosensitive unit 114 according to the third combined current I13 and the fourth combined current I14 by the control unit 130.

As such, the optical sensing circuit 100 provided in this embodiment may effectively obtain the first sensed value D11 of the first photosensitive unit 111, the second sensed value D12 of the second photosensitive unit 112, the third sensed value D13 of the third photosensitive unit 113, and the fourth sensed value D14 of the fourth photosensitive unit 114. Moreover, in this embodiment, the optical sensing circuit 100 may obtain the sensed results of four photosensitive units by applying just two ADCs; hence, the optical sensing circuit 100 provided in this embodiment may effectively reduce the circuit area occupied by the ADC circuit in the optical sensing circuit 100.

In addition, in this embodiment, four photosensitive units exemplarily correspond to two arithmetic units, for instance, while the configuration manner and/or the circuit coupling manner the photosensitive units and the arithmetic units provided in the disclosure is not limited to what is shown in FIG. 1. For instance, in an embodiment, the second photosensitive unit 112 and the third photosensitive unit 113 shown in FIG. 1 may refer to the same photosensitive unit. Thereby, the third photosensitive unit (which may correspond to the fourth photosensitive unit 114 in FIG. 1) may provide the third sensing current (which may correspond to the fourth sensing current I04 in FIG. 1) during the first light sensing period and provide another third sensing current (which may correspond to the another fourth sensing current I04′ in FIG. 1) during the second light sensing period. The second arithmetic unit 122 may generate a third combined current according to the second sensing current and the third sensing current during the first light sensing period (which may correspond to the added second sensing current I02 and fourth sensing current I04 in FIG. 1) and generate a fourth combined current according to another second sensing current and another third sensing current during the second light sensing period (which may correspond to the another second sensing current I02′ and the another fourth sensing current I04′ subtracted from each other as shown in FIG. 1). Therefore, the control unit 130 may generate the second sensed value of the second photosensitive unit according to the third combined current and the fourth combined current (which may correspond to the second sensed value D12 depicted in FIG. 1) and generate the third sensed value of the third photosensitive unit (which may correspond to the fourth sensed value D14 depicted in FIG. 1).

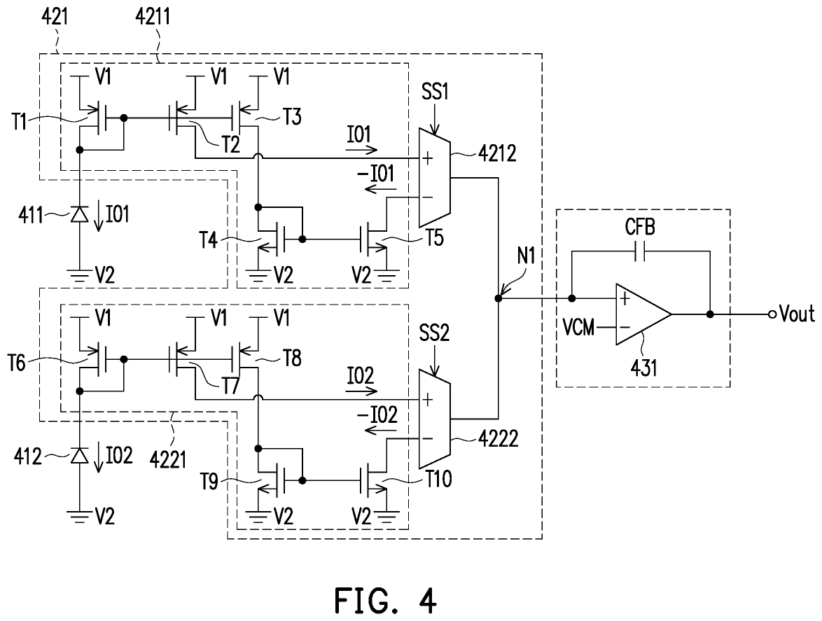

FIG. 4 is a schematic view of an arithmetic unit according to another embodiment of the disclosure. With reference to FIG. 4, the arithmetic unit provided in the disclosure may be implemented, for instance, in form of the arithmetic unit 421 shown in FIG. 4. In this embodiment, the arithmetic unit 421 is coupled to a first photosensitive unit 411 and a second photosensitive unit 412 and is coupled to a first input terminal of an operational amplifier 431 through a circuit node N1. A second input terminal of the operational amplifier 431 is coupled to a reference voltage VCM. A capacitor CFB is coupled between the first input terminal of the operational amplifier 431 and an output terminal Vout of the operational amplifier 431. The output terminal Vout of the operational amplifier 431 may read out an output result of the arithmetic unit 421. The operational amplifier 431 and the capacitor CFB may be a part of the ADC described in the above embodiments, which should however not be construed as a limitation in the disclosure.

In this embodiment, the arithmetic unit 421 includes a first current mirror circuit 4211, a second current mirror circuit 4221, a first multiplexer 4212, and a second multiplexer 4222. The first photosensitive unit 411 and the second photosensitive unit 412 may be a PD, respectively. The output terminal of the first multiplexer 4212 and an output terminal of the second multiplexer 4222 are coupled to the operational amplifier 431 by the circuit node N1 or coupled to the control unit 130 shown in FIG. 1. An anode of the first photosensitive unit 411 is coupled to a voltage V2, and a cathode of the first photosensitive unit 411 is coupled to the first current mirror circuit 4211. An anode of the second photosensitive unit 412 is coupled to the voltage V2, and a cathode of the second photosensitive unit 412 is coupled to the second current mirror circuit 4221. The voltage V2 may be, for instance, a ground voltage.

In this embodiment, the first current mirror circuit 4211 includes a first transistor T1, a second transistor T2, a third transistor T3, a fourth transistor T4, and a fifth transistor T5. A first terminal of the first transistor T1 is coupled to a voltage V1. The voltage V1 may be, for instance, a device operating voltage (VDD). A second terminal of the first transistor T1 is coupled to the cathode of the first photosensitive unit 411. A control terminal of the first transistor T1 is coupled to the second terminal of the first transistor T1. A first terminal of the second transistor T2 is coupled to the voltage V1. A second terminal of the second transistor T2 is coupled to the first input terminal of the first multiplexer 4212, and a control terminal of the second transistor T2 is coupled to the control terminal of the first transistor T1. A first terminal of the third transistor T3 is coupled to the voltage V1. A control terminal of the third transistor T3 is coupled to the control terminal of the first transistor T1. A first terminal of the fourth transistor T4 is coupled to a second terminal of the third transistor T3. A second terminal of the fourth transistor T4 is coupled to the voltage V2. A control terminal of the fourth transistor T4 is coupled to the first terminal of the fourth transistor T4. A first terminal of the fifth transistor T5 is coupled to the second input terminal of the first multiplexer 4212. A second terminal of the fifth transistor T5 is coupled to the voltage V2. A control terminal of the fifth transistor T5 is coupled to the control terminal of fourth transistor T4.

In this embodiment, the first transistor T1, the second transistor T2, and the third transistor T3 are respectively a p-type transistor, and the fourth transistor T4 and the fifth transistor T5 are respectively an n-type transistor. In this embodiment, the second terminal of the second transistor T2 may replicate the first sensing current I01 generated by the first photosensitive unit 411 during the first light sensing period and the second light sensing period. The first terminal of the fifth transistor T5 may replicate a first reverse sensing current 401 generated by the first photosensitive unit 411 during the first light sensing period and the second light sensing period.

In this embodiment, the second current mirror circuit 4221 includes a sixth transistor T6, a seventh transistor T7, an eighth transistor T8, a ninth transistor T9, and a tenth transistor T10. A first terminal of the sixth transistor T6 is coupled to the voltage V1. A second terminal of the sixth transistor T6 is coupled to the cathode of the first photosensitive unit 411. A control terminal of the sixth transistor T6 is coupled to the second terminal of the sixth transistor T6. A first terminal of the seventh transistor T7 is coupled to the voltage V1. A second terminal of the seventh transistor T7 is coupled to the first input terminal of the first multiplexer 4212, and a control terminal of the seventh transistor T7 is coupled to the control terminal of the sixth transistor T6. A first terminal of the eighth transistor T8 is coupled to the voltage V1. A control terminal of the eighth transistor T8 is coupled to the control terminal of the sixth transistor T6. A first terminal of the ninth transistor T9 is coupled to a second terminal of the eighth transistor T8. A second terminal of the ninth transistor T9 is coupled to the voltage V2. A control terminal of the ninth transistor T9 is coupled to the first terminal of the ninth transistor T9. A first terminal of the tenth transistor T10 is coupled to the second input terminal of the first multiplexer 4212. A second terminal of the tenth transistor T10 is coupled to the voltage V2. A control terminal of the tenth transistor T10 is coupled to the control terminal of the ninth transistor T9.

In this embodiment, the sixth transistor T6, the seventh transistor T7, and the eighth transistor T8 are respectively a p-type transistor, and the ninth transistor T9 and the tenth transistor T10 are respectively an n-type transistor. In this embodiment, the second terminal of the seventh transistor T7 may replicate the second sensing current I02 generated by the second photosensitive unit 412 during the first light sensing period and the second light sensing period. The first terminal of the tenth transistor T10 may replicate a second reverse sensing current −I02 generated by the second photosensitive unit 412 during the first light sensing period and the second light sensing period.

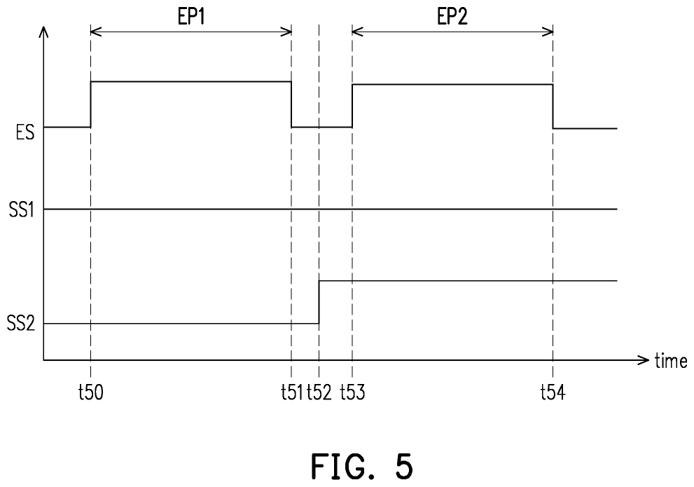

FIG. 5 is a schematic view of a timing sequence of signals according to another embodiment of the disclosure. With reference to FIG. 4 and FIG. 5, the signal timing sequence shown in FIG. 5 is taken as an example, it is assumed that the first photosensitive unit 411 respectively generates the same first sensing current I01 during the first light sensing period EP1 and the second light sensing period EP2 (e.g., I01=I01′ provided in the previous embodiment), and it is assumed that the second photosensitive unit 412 respectively generates the same second sensing current I02 during the first light sensing period EP1 and the second light sensing period EP2 (e.g., I02=I02′ provided in the previous embodiment). As such, the first input terminal of the first multiplexer 4212 receives the first sensing current I01, and the second input terminal of the first multiplexer 4212 receives the first reverse sensing current −I01. The first input terminal of the second multiplexer 4222 receives the second sensing current I02, and the second input terminal of the second multiplexer 4222 receives the second reverse sensing current −I02.

In this embodiment, the first multiplexer 4212 and the second multiplexer 4222 may respectively receive the switch signals SS1 and SS2 provided by a control unit (e.g., the control unit 130 shown in FIG. 1). As shown in FIG. 5, the switch signal SS1 may stay at a low voltage level from a timing t50 to a timing t54, for instance, so that the first multiplexer 4212 keeps on outputting the first sensing current I01 (transmitted from the first input terminal) from the output terminal during the first light sensing period EP1 from the timing t50 to a timing t51 and during the second light sensing period EP2 from a timing t53 to the timing t54. The switch signal SS2 may stay at a low voltage level from the timing t50 to a timing t52, for instance, and the switch signal SS2 may be switched to a high voltage level between the timing t52 and the timing t54, so that the second multiplexer 4222 outputs the second sensing current I02 (transmitted from the first input terminal) from the output terminal during the first light sensing period EP1 from the timing t50 to the timing t51 and outputs the second reverse sensing current −I02 (transmitted from the second input terminal) from the output terminal during the second light sensing period EP2 from the timing t53 to the timing t54.

In other words, the first multiplexer 4212 and the second multiplexer 4222 output the first sensing current I01 and the second sensing current I02 during the first light sensing period EP1, so that the circuit node N1 transmits the first combined current (i.e., I01+I02) to the operational amplifier 431 or a back-end control unit (e.g., the control unit 130 in FIG. 1). The first multiplexer 4212 and the second multiplexer 4222 output the first sensing current I01 and the second reverse sensing current −I02 during the second light sensing period EP2, so that the circuit node N1 transmits the second combined current (i.e., I01−I02) to the back-end control unit. Thereby, the back-end control unit may perform the operations described in the previous embodiments as shown in FIG. 1 to FIG. 3, so as to generate the first sensed value of the first photosensitive unit 411 and the second sensed value of the second photosensitive unit 412.

To sum up, in the optical sensing circuit and the optical sensing method provided in one or more embodiments of the disclosure, the arithmetic unit may be effectively applied in two adjacent exposure periods to combine the sensing currents of the two photosensitive units according to a specific arithmetic method, and the respective sensed values of the two photosensitive units are calculated by the back-end control circuit. In this way, the optical sensing circuit and optical sensing method of the disclosure may effectively generate the sensed value of the photosensitive unit, and may also effectively reduce the circuit area occupied by the readout circuit in the optical sensing circuit.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. An optical sensing circuit, comprising:
a first photosensitive unit and a second photosensitive unit, configured to provide a sensing current during a light sensing period;
an arithmetic unit, coupled to the first photosensitive unit and the second photosensitive unit and configured to generate a combined current according to the sensing current during the light sensing period; and
a control unit, coupled to the arithmetic unit and configured to generate a first sensed value of the first photosensitive unit and a second sensed value of the second photosensitive unit according to the combined current.

2. The optical sensing circuit according to claim 1, wherein the light sensing period comprises a first light sensing period and a second light sensing period,
wherein the first photosensitive unit provides a first photosensitive current during the first light sensing period and provides another first photosensitive current during the second light sensing period,
wherein the second photosensitive unit provides a second photosensitive current during the first light sensing period and provides another second photosensitive current during the second light sensing period,
wherein the arithmetic unit generates a first combined current according to the first sensing current and the second sensing current during the first light sensing period and generates a second combined current according to the another first sensing current and the another second sensing current during the second light sensing period,
wherein the control unit generates the first sensed value of the first photosensitive unit and the second sensed value of the second photosensitive unit according to the first combined current and the second combined current.

3. The optical sensing circuit according to claim 2, wherein the control unit comprises:
a first analog to digital converter, coupled to the arithmetic unit and configured to convert the first combined current and the second combined current into a first digital signal and a second digital signal; and
a control circuit, coupled to the first analog to digital converter and configured to calculate the first sensed value and the second sensed value according to a first phase count value of the first digital signal and a second phase count value of the second digital signal.

4. The optical sensing circuit according to claim 3, wherein the control circuit adds the first phase count value and the second phase count value to obtain a first arithmetic value and subtracts the first phase count value and the second phase count value from each other to obtain a second arithmetic value,
wherein the control circuit respectively divides the first arithmetic value and the second arithmetic value by a reference value to obtain the first sensed value and the second sensed value, wherein the reference value is a positive integer.

5. The optical sensing circuit according to claim 3, wherein the control circuit is further coupled to the first photosensitive unit and the second photosensitive unit, and the control circuit output an enabling signal to the first photosensitive unit and the second photosensitive unit, so that the first photosensitive unit and the second photosensitive unit respectively perform a light sensing operation during the first light sensing period and the second light sensing period.

6. The optical sensing circuit according to claim 2, wherein the arithmetic unit comprises:
a first current mirror circuit, coupled to the first photosensitive unit and configured to output the first sensing current and a first reverse sensing current;
a first multiplexer, coupled to the first current mirror circuit, wherein a first input terminal of the first multiplexer receives the first sensing current, and a second input terminal of the first multiplexer receives the first reverse sensing current;
a second current mirror circuit, coupled to the second photosensitive unit and configured to output the second sensing current and a second reverse sensing current; and
a second multiplexer, coupled to the second current mirror circuit, wherein a first input terminal of the second multiplexer receives the second sensing current, and a second input terminal of the second multiplexer receives the second reverse sensing current,
wherein an output terminal of the first multiplexer and an output terminal of the second multiplexer are coupled to the control unit by a circuit node.

7. The optical sensing circuit according to claim 6, wherein the first multiplexer and the second multiplexer output the first sensing current and the second sensing current during the first light sensing period, so that the circuit node transmits the first combined current to the control unit,
wherein the first multiplexer and the second multiplexer output the first sensing current and the second reverse sensing current during the second light sensing period, so that the circuit node transmits the second combined current to the control unit.

8. The optical sensing circuit according to claim 6, wherein the first current mirror circuit comprises:
a first transistor, wherein a first terminal of the first transistor is coupled to a first voltage, a second terminal of the first transistor is coupled to the first photosensitive unit, and a control terminal of the first transistor is coupled to the second terminal of the first transistor;
a second transistor, wherein a first terminal of the second transistor is coupled to the first voltage, a second terminal of the second transistor is coupled to the first input terminal of the first multiplexer, and a control terminal of the second transistor is coupled to the control terminal of the first transistor;
a third transistor, wherein a first terminal of the third transistor is coupled to the first voltage, and a control terminal of the third transistor is coupled to the control terminal of the first transistor;
a fourth transistor, wherein a first terminal of the fourth transistor is coupled to a second terminal of the third transistor, a second terminal of the fourth transistor is coupled to a second voltage, and a control terminal of the fourth transistor is coupled to the first terminal of the fourth transistor; and
a fifth transistor, wherein a first terminal of the fifth transistor is coupled to the second input terminal of the first multiplexer, a second terminal of the fifth transistor is coupled to the second voltage, and a control terminal of the fifth transistor is coupled to the control terminal of the fourth transistor.

9. The optical sensing circuit according to claim 8, wherein the first transistor, the second transistor, and the third transistor are respectively a p-type transistor, and the fourth transistor and the fifth transistor are respectively an n-type transistor.

10. The optical sensing circuit according to claim 2, further comprising:
a third photosensitive unit, configured to provide a third sensing current during the first light sensing period and provide another third sensing current during the second light sensing period;
a fourth photosensitive unit, configured to provide a fourth sensing current during the first light sensing period and another fourth sensing current during the second light sensing period; and
another arithmetic unit, coupled to the third photosensitive unit and the fourth photosensitive unit and configured to generate a third combined current according to the third sensing current and the fourth sensing current during the first light sensing period and generate a fourth combined current according to the another third sensing current and the another fourth sensing current during the second light sensing period,
wherein the control unit generates a third sensed value of the third photosensitive unit and a fourth sensed value of the fourth photosensitive unit according to the third combined current and the fourth combined current.

11. The optical sensing circuit according to claim 10, wherein the first photosensitive unit, the second photosensitive unit, the third photosensitive unit, and the fourth photosensitive unit are sensing pixels of different colors, respectively.

12. The optical sensing circuit according to claim 2, further comprising:
a third photosensitive unit, configured to provide a third sensing current during the first light sensing period and another third sensing current during the second light sensing period; and
another arithmetic unit, coupled to the second photosensitive unit and the third photosensitive unit and configured to generate a third combined current according to the second sensing current and the third sensing current during the first light sensing period and generate a fourth combined current according to the another second sensing current and the another third sensing current during the second light sensing period,
wherein the control unit generates the second sensed value of the second photosensitive unit and a third sensed value of the third photosensitive unit according to the third combined current and the fourth combined current.

13. The optical sensing circuit according to claim 1, wherein each of the first photosensitive unit and the second photosensitive unit comprises a photodiode.

14. An optical sensing method, comprising:
providing a sensing current during a light sensing period by a first photosensitive unit and a second photosensitive unit;
generating a combined current according to the sensing current during the light sensing period by an arithmetic unit; and
generating a first sensed value of the first photosensitive unit and a second sensed value of the second photosensitive unit according to the combined current by a control unit.

15. The optical sensing method according to claim 14, wherein the step of providing the sensing current comprises:
providing a first sensing current during a first light sensing period by the first photosensitive unit;
providing a second sensing current during the first light sensing period by the second photosensitive unit;
providing another first sensing current during a second light sensing period by the first photosensitive unit; and
providing another second sensing current during the second light sensing period by the second photosensitive unit,
wherein the step of generating the combined current comprises:
generating a first combined current according to the first sensing current and the second sensing current during the first light sensing period by the arithmetic unit; and
generating a second combined current according to the another first sensing current and the another second sensing current during the first light sensing period by the arithmetic unit,
wherein the control unit generates the first sensed value of the first photosensitive unit and the second sensed value of the second photosensitive unit according to the first combined current and the second combined current.

16. The optical sensing method according to claim 15, wherein the step of generating the first sensed value and the second sensed value comprises:
converting the first combined current and the second combined current into a first digital signal and a second digital signal by a first analog to digital converter of the control unit; and
calculating the first sensed value and the second sensed value according to a first phase count value of the first digital signal and a second phase count value of the second digital signal by a control circuit of the control unit.

17. The optical sensing method according to claim 16, wherein the step of calculating the first sensed value and the second sensed value according to the first phase count value of the first digital signal and the second phase count value of the second digital signal comprises:
adding the first phase count value and the second phase count value by the control circuit to obtain a first arithmetic value, and subtracting the first phase count value and the second phase count value from each other to obtain a second arithmetic value; and
respectively dividing the first arithmetic value and the second arithmetic value by a reference value by the control circuit to obtain the first sensed value and the second sensed value, wherein the reference value is a positive integer.

18. The optical sensing method according to claim 17, further comprising:
outputting an enabling signal to the first photosensitive unit and the second photosensitive unit by the control circuit, so that the first photosensitive unit and the second photosensitive unit perform a light sensing operation during the first light sensing period and the second light sensing period, respectively.

19. The optical sensing method according to claim 15, further comprising:
providing a third sensing current by a third photosensitive unit during the first light sensing period;
providing a fourth sensing current by a fourth photosensitive unit during the first light sensing period;
generating a third combined current according to the third sensing current and the fourth sensing current during the first light sensing period by another arithmetic unit;
providing another third sensing current during the second light sensing period by the third photosensitive unit;
providing another fourth sensing current during the second light sensing period by the fourth photosensitive unit; and
generating a fourth combined current according to the another third sensing current and the another fourth sensing current during the second light sensing period by the another arithmetic unit; and
generating a third sensed value of the third photosensitive unit and a fourth sensed value of the fourth photosensitive unit according to the third combined current and the fourth combined current by the control unit.

20. The optical sensing method according to claim 15, further comprising:
providing a third sensing current during the first light sensing period by a third photosensitive unit;
generating a third combined current according to the second sensing current and the third sensing current during the first light sensing period by another arithmetic unit;
providing another third sensing current during the second light sensing period by the third photosensitive unit; and
generating a fourth combined current according to the another second sensing current and the another third sensing current during the second light sensing period by the another arithmetic unit; and
generating the second sensed value of the second photosensitive unit and a third sensed value of the third photosensitive unit according to the third combined current and the fourth combined current by the control unit.
